(19) United States
(12) Patent Application Publication
(10) Pub. No.: US 2010/0155797 A1
(43) Pub. Date: Jun. 24, 2010

(54) CMOS image sensors

(75) Inventors: Jun-Taek Lee, Hwaseong-si (KR); Jun-Pyo Ko, Suwon-si (KR); Ji-Hoon Jung, Yongin-si (KR); Myoung-Bae Won, Nam-gu (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/654,234

(22) Filed: Dec. 15, 2009

(30) Foreign Application Priority Data
Dec. 24, 2008 (KR) 10-2008-0133536

(51) Int. Cl. H01L 31/112; H01L 31/0232

(52) U.S. Cl. 257/292; 438/70; 257/E31.079; 257/E31.127

(57) ABSTRACT

CMOS image sensors and methods of manufacturing the same are provided, the CMOS image sensors include an epitaxial layer, a photodiode, a transfer transistor, CMOS transistors, first metal wirings and a second metal wiring formed on a substrate. The substrate may have a photodiode region, a floating diffusion region, an active pixel sensor (APS) array circuit region and a peripheral circuit region. The photodiode may be formed on the epitaxial layer in the photodiode region. The transfer transistor may be formed on the epitaxial layer in the floating diffusion region. The CMOS transistors may be formed on the epitaxial layer in the APS array circuit region and the peripheral circuit region. The first metal wirings may be formed over the photodiode region. The second metal wiring may be formed on one of the first metal wirings. The second metal wiring may be located higher than the first metal wirings.

### CROSS-REFERENCE TO RELATED APPLICATIONS

This application claims priority under 35 USC §119 to Korean Patent Application No. 2008-133536, filed on Dec. 24, 2008 in the Korean Intellectual Property Office (KIPO), the contents of which are herein incorporated by reference in their entirety.

### BACKGROUND

1. Field

Example embodiments of the inventive concepts relate to CMOS image sensors and methods of manufacturing the same. Other example embodiments of the inventive concepts relate to CMOS image sensors capable of preventing the generation of column fixed pattern noises (CFPN) or row fixed pattern noises (RFPN) by enlarging a light receiving area and preventing the formation of a bridge between adjacent metal wirings and methods of manufacturing the CMOS image sensors.

2. Description of the Related Art

Recently, as the information communication industry and digital electronic devices develop, image sensors are widely used in diverse fields (e.g., digital cameras, camcorders, cellular phones, personal communication systems, game devices, guard cameras, medical micro cameras, etc.). As semiconductor devices become more highly-integrated, an area of a unit cell is greatly reduced, so that a width of patterns and an interval between the patterns may be narrowed (or become smaller). In contrast, the semiconductor devices require better electrical characteristics and/or lower power consumption.

Generally, an image sensor cell may include an active pixel sensor (APS) array region having photodiodes, and a peripheral circuit region.

The APS array region may include a transfer transistor, a reset transistor, a selection transistor and a drive transistor between a light-receiving region and a floating diffusion region.

In order to supply voltages to the transistors, it may be necessary to arrange a pair of metal wirings at both upper sides of the light-receiving region.

If the metal wirings are arranged closely, a bridge between the adjacent metal wirings may be generated. The bridge may cause a column fixed pattern noise (CFPN) or a row fixed pattern noise (RFPN) so that abnormal output images may be generated.

### SUMMARY

Example embodiments of the inventive concepts relate to CMOS image sensors and methods of manufacturing the same. Other example embodiments of the inventive concepts relate to CMOS image sensors capable of preventing the generation of column fixed pattern noises (CFPN) or row fixed pattern noises (RFPN) by enlarging a light receiving area and preventing the formation of a bridge between adjacent metal wirings and methods of manufacturing the CMOS image sensors.

Example embodiments of the inventive concepts provide CMOS image sensors that may be capable of preventing generation of a bridge between metal wirings. Example embodiments of the inventive concepts also provide methods of manufacturing the above-mentioned CMOS image sensors.

According to example embodiments of the inventive concepts, there is provided a CMOS image sensor. The CMOS image sensor may include a substrate, an epitaxial layer, a photodiode, a transfer transistor, CMOS transistors, first metal wirings and second metal wiring. The substrate may have a photodiode region, a floating diffusion region, an active pixel sensor (APS) array circuit region and a peripheral circuit region. The epitaxial layer may be formed on the substrate. The photodiode may be formed on the epitaxial layer in the photodiode region. The transfer transistor may be formed on the epitaxial layer in the floating diffusion region. The CMOS transistors may be formed on the epitaxial layer in the APS array circuit region and the peripheral circuit region. The first metal wirings may be formed over the photodiode region. The second metal wiring may be formed on at least one of the first metal wirings. The second metal wiring may be located higher than the first metal wirings.

In example embodiments of the inventive concepts, the first metal wirings may be bent against a light-receiving region of the photodiode to enlarge an area of the light-receiving region.

In example embodiments of the inventive concepts, the CMOS image sensor may include a lens formed over a light-receiving region of the photodiode.

In example embodiments of the inventive concepts, the first metal wirings may be bent against the light-receiving region and the second metal wiring may be bent towards the light-receiving region to enlarge an area of the light-receiving region.

In example embodiments of the inventive concepts, the first metal wirings and the second metal wiring may be arranged on different insulating interlayers.

According to example embodiments of the inventive concepts, there is provided a method of manufacturing a CMOS image sensor. In the method of manufacturing the CMOS image sensor, an epitaxial layer may be formed on a substrate. The substrate may have a photodiode region, a floating diffusion region, an active pixel sensor (APS) array circuit region and a peripheral circuit region. Channel regions may be formed on the epitaxial layer in the floating diffusion region. A photodiode may be formed on the epitaxial layer in the photodiode region. A transfer transistor and a plurality of CMOS transistors may be formed on the epitaxial layer. A first insulating interlayer may be formed on the substrate and electrodes of the transfer transistor and the CMOS transistors. First metal contacts may be formed through the first insulating interlayer and electrically connected the photodiode. First metal wirings may be formed on the metal contacts. A second insulating interlayer may be on the first insulating interlayer to cover the first metal wirings. A second metal contact may be formed through the second insulating interlayer and electrically connected to at least one of the first metal wirings with the second metal contact. A second metal wiring may be formed on the second metal contact.

In example embodiments of the inventive concepts, the method may include forming a protecting layer on the second insulating interlayer to cover the second metal wiring, and forming a lens on the protecting layer. In example embodiments of the inventive concepts, the method may include forming a color filter layer between the protecting layer and the lens.

In example embodiments of the inventive concepts, the method may include connecting the first metal wirings with a Vₒᵤₜ terminal. In example embodiments of the inventive concepts, the method may include connecting the second metal wiring with a V_{dd} terminal.

According to example embodiments of the inventive concepts, the second metal wiring may be located higher than the first metal wiring, so that a bridge may not be formed between the first metal wirings and the second metal wiring. As such, a column fixed pattern noise (CFPN) and/or a row fixed pattern noise (RFPN) may not be generated in the CMOS image sensor, thereby the CMOS image sensor may display a clearer image.

### BRIEF DESCRIPTION OF THE DRAWINGS

Example embodiments of the inventive concepts will be more clearly understood from the following detailed description taken in conjunction with the accompanying drawings. FIGS. 1 to 15 represent non-limiting, example embodiments of the inventive concepts as described herein.

FIG. 1 is a plan view illustrating a CMOS image sensor in accordance with example embodiments of the inventive concepts;

FIG. 2 is a perspective view illustrating metal wirings of the CMOS image sensor in FIG. 1;

FIG. 3 is a cross-sectional view illustrating the metal wirings of the CMOS image sensor in FIG. 1;

FIG. 4 is a plan view illustrating a CMOS image sensor in accordance with example embodiments of the inventive concepts;

FIG. 5 is a plan view illustrating a CMOS image sensor in accordance with example embodiments of the inventive concepts;

FIGS. 6 to 12 are cross-sectional views illustrating a method of manufacturing a CMOS image sensor;

FIG. 13 is a block diagram illustrating a system in accordance with example embodiments of the inventive concepts;

FIG. 14 is a block diagram illustrating a CMOS image sensing device in accordance with example embodiments of the inventive concepts; and

FIG. 15 is a perspective view illustrating a camera phone in accordance with example embodiments of the inventive concepts.

### DETAILED DESCRIPTION OF EXAMPLE EMBODIMENTS OF THE INVENTIVE CONCEPTS

Various example embodiments of the inventive concepts will now be described more fully with reference to the accompanying drawings in which some example embodiments of the inventive concepts are shown. However, specific structural and functional details disclosed herein are merely representative for purposes of describing example embodiments of the inventive concepts. Thus, the invention may be embodied in many alternate forms and should not be construed as limited to only example embodiments of the inventive concepts set forth herein. Therefore, it should be understood that there is no intent to limit example embodiments of the inventive concepts to the particular forms disclosed, but on the contrary, example embodiments of the inventive concepts are to cover all modifications, equivalents, and alternatives falling within the scope of the invention.

In the drawings, the thicknesses of layers and regions may be exaggerated for clarity, and like numbers refer to like elements throughout the description of the figures.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments of the inventive concepts only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the inventive concepts are described herein with reference to cross-sectional illustrations that are schematic illustrations of idealized example embodiments of the inventive concepts (and intermediate structures). As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the inventive concepts will be explained in detail with reference to the accompanying drawings.

Example embodiments of the inventive concepts relate to CMOS image sensors and methods of manufacturing the same. Other Example embodiments of the inventive concepts relate to CMOS image sensors capable of preventing the generation of column fixed pattern noises (CFPN) or row fixed pattern noises (RFPN) by enlarging a light receiving area and preventing the formation of a bridge between adjacent metal wirings and methods of manufacturing the CMOS image sensors.

### CMOS Image Sensor

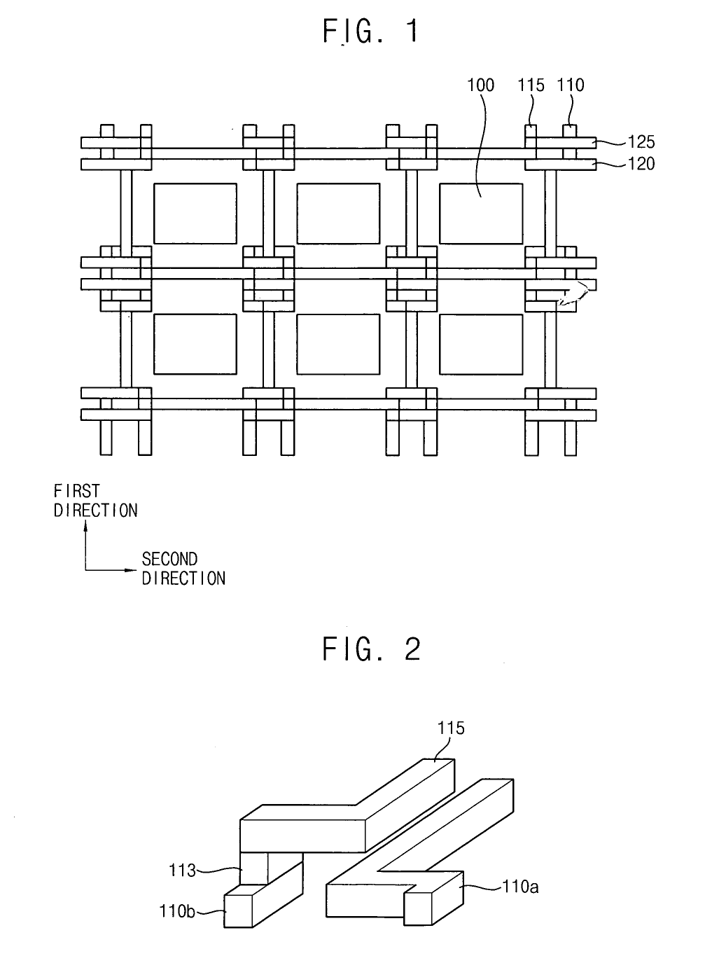

FIG. 1 is a plan view illustrating a CMOS image sensor in accordance with example embodiments of the inventive concepts.

Referring to FIG. 1, a light-receiving region 100 may include a region where an APS array may be formed. In example embodiments of the inventive concepts, the light-receiving region 100 may include a region where a photodiode may be formed. The CMOS image sensor may include a transfer gate, a floating diffusion gate, an APS transistor and a peripheral logic CMOS transistor (which are not shown).

The light-receiving region 100 may be operated by absorbing a blue color, a green color and/or a red color in a lens, a filter and an insulating interlayer.

The red color may have the longest wavelength of about 0.4 μm to about 5 μm. In order to allow the photodiode 100′ to receive a substantial amount of light without the generation of physical phenomena (e.g., refraction, an interference or the like), the photodiode 100′ may have a substantially large upper surface.

A first lower metal wiring 110 and a first upper metal wiring 115 may extend in a first direction over side upper portions of the light-receiving region 100. In example embodiments of the inventive concepts, the first upper metal wiring 115 may be located over the first lower metal wiring 110. The arrangement of the first upper metal wiring 115 and the first lower metal wiring 110 may prevent (or reduce the likelihood of) a bridge forming between the first upper metal wiring 115 and the first lower metal wiring 110. The first upper metal wiring 115 and the first lower metal wiring 110 may not cover the light-receiving region 100. The light-receiving region 100 may still have a substantially large upper surface. In example embodiments of the inventive concepts, the first lower metal wiring 110 may be electrically connected with a Vₒᵤₜ terminal. The first upper metal wiring 115 may be electrically connected with a V_{dd} terminal.

A second lower metal wiring 120 and a second upper metal wiring 125 may extend in a second direction, which may be substantially perpendicular to the first direction, over the side upper portions of the light-receiving region 100. In example embodiments of the inventive concepts, the second upper metal wiring 125 may be located over the second lower metal wiring 120. The arrangement of the second upper metal wiring 125 and the second lower metal wiring 120 may prevent (or reduce the likelihood of) a bridge forming between the second upper metal wiring 125 and the second lower metal wiring 120. The second upper metal wiring 125 and the second lower metal wiring 120 may not cover the light-receiving region 100. The light-receiving region 100 may have a substantially large upper surface.

In example embodiments of the inventive concepts, the first lower metal wiring 110 and the second lower metal wiring 120 may be substantially coplanar with each other. The first upper metal wiring 115 and the second upper metal wiring 125 may be substantially coplanar with each other.

FIG. 2 is a perspective view illustrating metal wirings of the CMOS image sensor in FIG. 1.

Referring to FIGS. 1 and 2, the first lower metal wiring 110 may include a first right metal wiring 110a and a first left metal wiring 110b. The first right metal wiring 110a and the first left metal wiring 110b may extend in the first direction. The first right metal wiring 110a and the first left metal wiring 110b may be arranged in parallel with each other on substantially the same plane. The first right metal wiring 110a may be bent (or extend) in the second direction against the light-receiving region 100.

A metal contact 113 may be formed on the first left metal wiring 110b. The first upper metal wiring 115 may be formed on the metal contact 113. The first upper metal wiring 115 may be located higher than the first lower metal wiring 110 by a distance equivalent to a thickness of the metal contact 113. The first upper metal wiring 115 may extend in the first direction between the first right metal wiring 110a and the first left metal wiring 110b. The first upper metal wiring 115 may be bent in the second direction toward the light-receiving region 100. The bent portion of the first upper metal wiring 115 may be positioned on the metal contact 113.

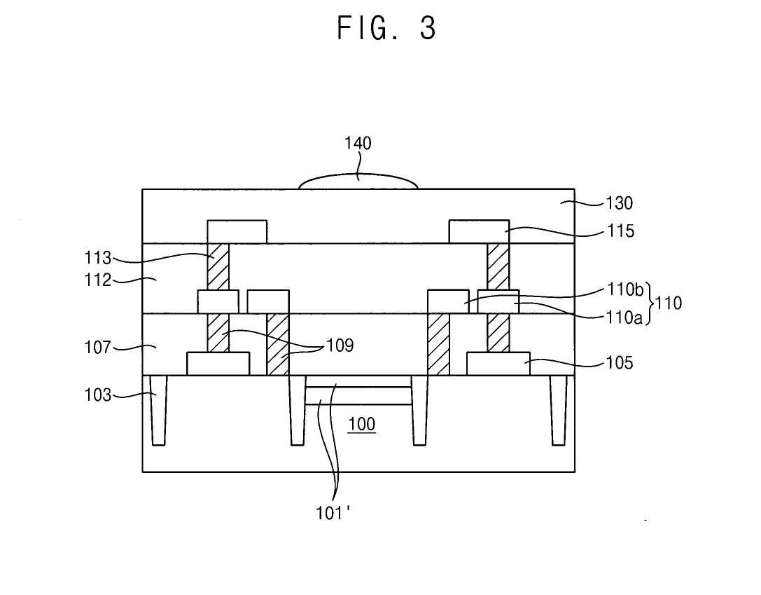

FIG. 3 is a cross-sectional view illustrating the light-receiving area and the metal wirings of the CMOS image sensor shown in FIG. 1.

Referring to FIG. 3, after forming the photodiode 100′, a gate structure 105 of a transfer transistor may be formed on a semiconductor substrate 101. A first insulating interlayer 107 may be formed on the semiconductor substrate 101 to cover the gate structure 105. Isolation layers 103 may be formed in the semiconductor substrate 101.

Via holes may be formed through the first insulating interlayer 107 to expose the gate structure 105 and the semiconductor substrate 101. The via holes may be filled with a first metal contact 109 to electrically connect the gate structure 105 with the first metal contact 109.

The first lower metal wiring 110 including the first right metal wiring 110a and the first left metal wiring 110b may be formed on the first metal contact 109. A second insulating interlayer 112 may be formed on the first insulating interlayer 107 to cover the first lower metal wiring 110.

Via holes may be formed through the second insulating interlayer 112 to expose the first lower metal wiring 110. The via holes may be filled with the second metal contact 113 to electrically connect the first lower metal wiring 110 with the second metal contact 113.

The first upper metal wiring 115 may be formed on the second metal contact 113. A protecting layer 130 may be formed on the second insulating interlayer 112 to cover the first upper metal wiring 115. A lens 140 may be formed on the protecting layer 130.

According to example embodiments of the inventive concepts, the upper metal wiring may be placed over the lower metal wiring, so that the light-receiving region may have a substantially large area. Because an insulating interlayer may be interposed between the upper metal wiring and the lower metal wiring, a bridge may not be generated between the upper metal wiring and the lower metal wiring, thereby preventing (or reducing) the output of abnormal images caused by a column fixed pattern noise (CFPN) or a row fixed pattern noise (RFPN).

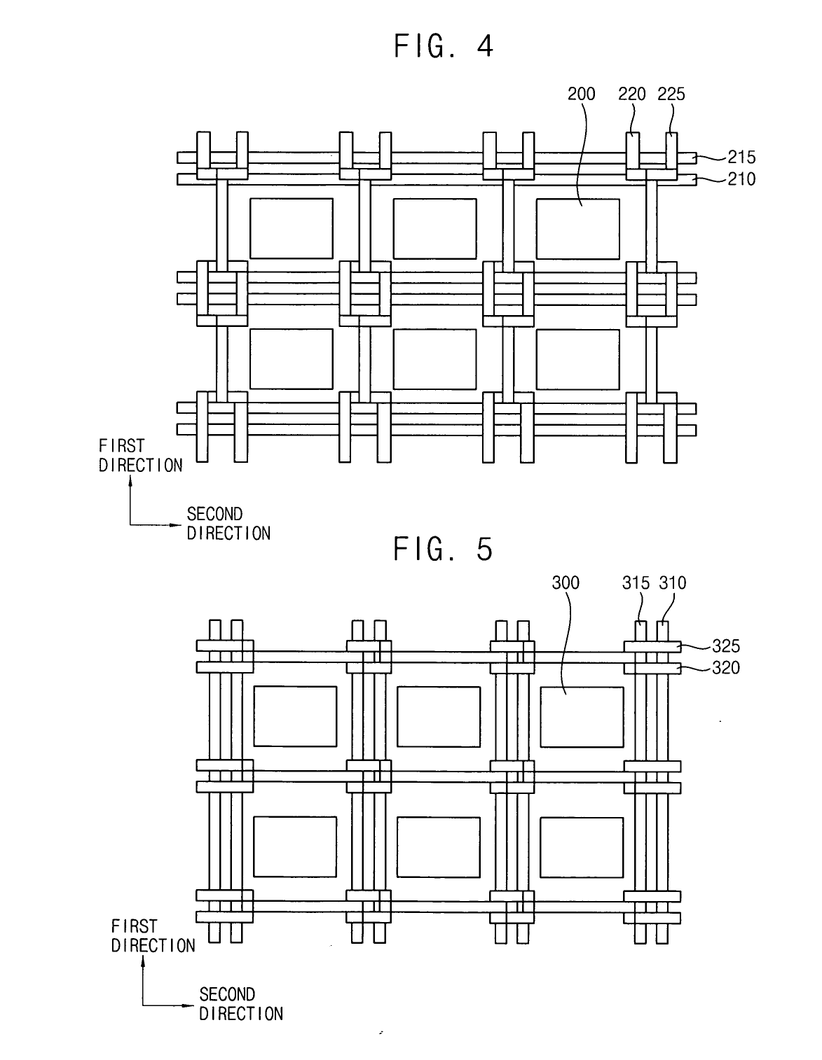

FIG. 4 is a plan view illustrating a CMOS image sensor in accordance with example embodiments of the inventive concepts.

Referring to FIG. 4, a light-receiving region 200 may include a region where an APS array may be formed. In example embodiments of the inventive concepts, the light-receiving region 200 may include a region where a photodiode may be formed. The CMOS image sensor may include a transfer gate, a floating diffusion gate, an APS transistor and a peripheral logic CMOS transistor (which are not shown).

In example embodiments of the inventive concepts, the CMOS image sensor may have a substantially small space where metal wirings may extend in a first direction. As such, a CFPN may be generated in the CMOS image sensor.

First metal wirings 210 and 215 may extend in a second direction substantially perpendicular to the first direction. A first insulating interlayer (not shown) may be formed on the first metal wirings 210 and 215. The CMOS image sensor may have a substantially large space where the first metal wirings 210 and 215 may extend in the second direction. The first metal wirings 210 and 215 may be substantially coplanar with each other.

A second metal wiring may be formed on the first insulating interlayer. The second metal wiring may extend in the first direction. The second metal wiring may include a second lower metal wiring 220 and a second upper metal wiring 225. The second lower metal wiring 220 may be bent in the second direction against the light-receiving region 200.

A metal contact (not shown) may be formed on the second lower metal wiring 220. The second upper metal wiring 225 may be formed on the metal contact. The second upper metal wiring 225 may be located higher than the second lower metal wiring 220 by a distance equivalent to a thickness of the metal contact. The second upper metal wiring 225 may be bent in the second direction toward the light-receiving region 200.

According to example embodiments of the inventive concepts, a bridge may not be generated between the upper metal wiring and the lower metal wiring. Abnormal images caused by a CFPN may not be generated.

FIG. 5 is a plan view illustrating a CMOS image sensor in accordance with example embodiments of the inventive concepts.

Referring to FIG. 5, a light-receiving region 300 may include a region where an APS array may be formed. In example embodiments of the inventive concepts, the light-receiving region 100 may include a region where a photodiode may be formed. The CMOS image sensor may include a transfer gate, a floating diffusion gate, an APS transistor and a peripheral logic CMOS transistor (which are not shown).

In example embodiments of the inventive concepts, the CMOS image sensor may have a substantially small space where metal wirings may extend in a second direction. As such, a RFPN may be generated in the CMOS image sensor.

First metal wirings 310 and 315 may extend in a first direction substantially perpendicular to the second direction. A first insulating interlayer (not shown) may be formed on the first metal wirings 310 and 315. The CMOS image sensor may have a substantially large space where the first metal wirings 310 and 315 may extend in the first direction. The first metal wirings 310 and 315 may be substantially coplanar with each other.

A second metal wiring may be formed on the first insulating interlayer. The second metal wiring may extend in the second direction. The second metal wiring may include a second lower metal wiring 320 and a second upper metal wiring 325. The second lower metal wiring 320 may be bent in the second direction against the light-receiving region 300.

A metal contact (not shown) may be formed on the second lower metal wiring 320. The second upper metal wiring 325 may be formed on the metal contact. The second upper metal wiring 325 may be located higher than the second lower metal wiring 320 by distance equivalent to a thickness of the metal contact. The second upper metal wiring 325 may be bent in the second direction toward the light receiving region 300.

According to example embodiments of the inventive concepts, a bridge may not be generated between the upper metal wiring and the lower metal wiring. Abnormal images caused by an RFPN may not be generated.

### Method of Manufacturing a CMOS Image Sensor

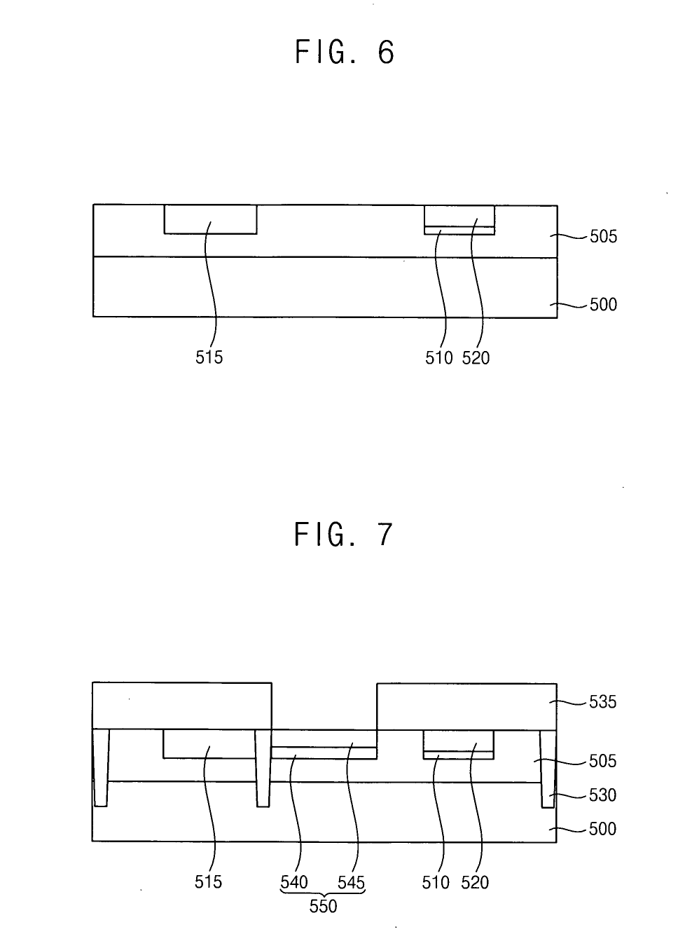

FIGS. 6 to 12 are cross-sectional views illustrating a method of manufacturing a CMOS image sensor.

Referring to FIG. 6, a semiconductor substrate 500 may be prepared. In example embodiments of the inventive concepts, the semiconductor substrate 500 may include an N-type substrate.

The semiconductor substrate 500 may have a region where an APS array may be formed, and a region where common elements may be formed. In example embodiments of the inventive concepts, the semiconductor substrate 500 may have a first region where a photodiode may be formed, and a second region where a transfer gate and a floating diffusion region may be formed.

A first conductive epitaxial layer 505 may be formed on the semiconductor substrate 500. In example embodiments of the inventive concepts, various semiconductor structures (e.g., a deep well) (not shown) may be formed on the first conductive epitaxial layer 505. The first conductive epitaxial layer 505 may have a thickness of about 5 nm to about 15 nm.

A first conductive impurity region 510 may be formed in the first conductive epitaxial layer 505. In example embodiments of the inventive concepts, the first conductive impurity region 510 may be used as a first channel of the transfer transistor.

Impurities may be implanted into a portion of the first conductive epitaxial layer 505 on the first conductive impurity region 510 to form a second conductive impurity region 520. A third impurity region 515 may be formed in an upper surface of the first conductive epitaxial layer 505.

Referring to FIG. 7, isolation layers 530 may be formed in the first conductive epitaxial layer 505 and the semiconductor substrate 500. In example embodiments of the inventive concepts, the isolation layers 530 may have different thicknesses in accordance with the position of the isolation layers 530. For example, the isolation layer 530 between the photodiodes may have a thickness different from that of the isolation layer 530 between semiconductor structures.

In example embodiments of the inventive concepts, the photodiode may be operated by absorbing a blue color, a green color and a red color in the first epitaxial layer 505. Because the red color may have the longest wavelength of about 0.4 μm to about 5 μm, the photodiode may have a thickness of no less than about 2 μm.

The photodiode 550 may be formed in the upper surface of the first conductive epitaxial layer 505. In example embodiments of the inventive concepts, a mask 535 may be formed on the first conductive epitaxial layer 505. Impurities may be implanted into the first conductive epitaxial layer 505 using the mask 535 as an ion implantation mask to form the photodiode 550. The mask 535 may subsequently be removed by a stripping process and/or an ashing process.

In example embodiments of the inventive concepts, the photodiode 550 may have a vertical structure. A first photodiode impurity region 540 may be formed in the first conductive epitaxial layer 505. A second photodiode impurity region 545 may be formed on the first photodiode impurity region 540 to form the photodiode 550. A depletion region may be formed at an interface between the photodiode 550 and the first conductive epitaxial layer 505.

In example embodiments of the inventive concepts, the photodiode 550 may capture all of the red color under a condition that the thickness of the photodiode 550 may be greater than the wavelength of the red color. The photodiode 550 may have a thickness of about 5 μm.

In example embodiments of the inventive concepts, a portion of the first conductive epitaxial layer 505 under the photodiode 550 may correspond to the depletion region. If the depletion region has a substantially large area, an electrical crosstalk may be reduced. It may be necessary to control a concentration of the impurities in the photodiode 550.

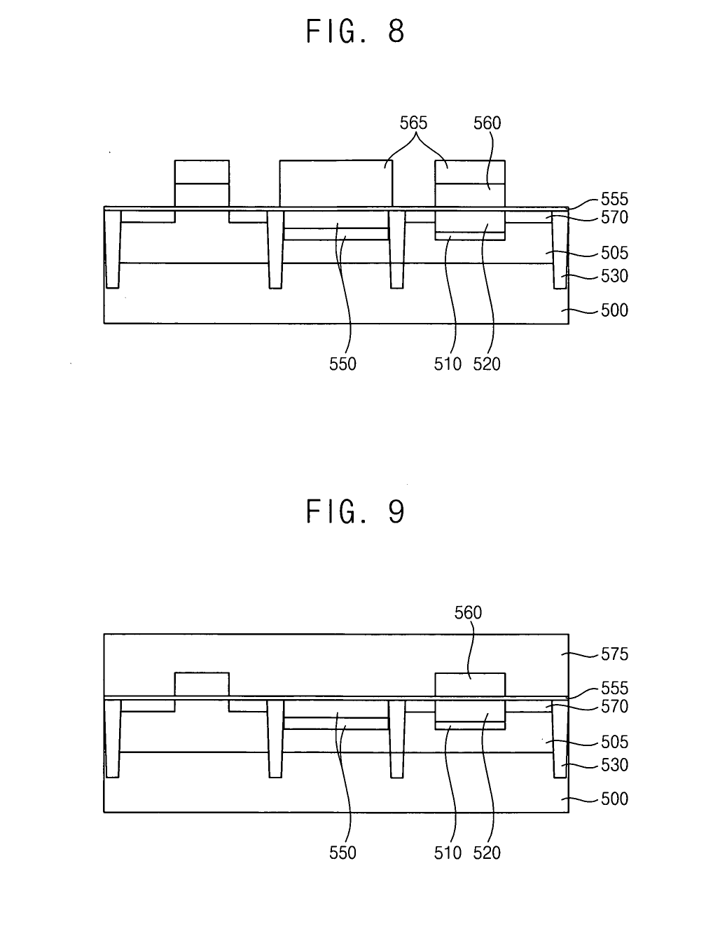

Referring to FIG. 8, a gate insulating layer 555 may be formed on the first epitaxial layer 505, the photodiode 550, the isolation layers 530 and the second impurity region 520. A gate electrode 560 may be formed on the gate insulating layer 555 over the second impurity region 520. A photoresist pattern 565 may be formed on the gate electrode 560 and the photodiode 550. Impurities may be implanted into the first epitaxial layer 505 using the photoresist pattern 565 as an ion implantation mask to form source/drain regions 570. Additionally, spacers (not shown) may be formed on sidewalls of the gate structure 560. Heavily doped source/drain regions may be formed in the source/drain regions 570. The photoresist pattern 565 may subsequently be removed by a stripping process and/or an ashing process.

Referring to FIG. 9, a first insulating interlayer 575 may be formed on the gate insulating layer 555 to cover the gate structure 560. In example embodiments of the inventive concepts, the first insulating interlayer 575 may be formed by a chemical vapor deposition (CVD) process. The first insulating interlayer 575 may be planarized by a chemical mechanical polishing (CMP) process.

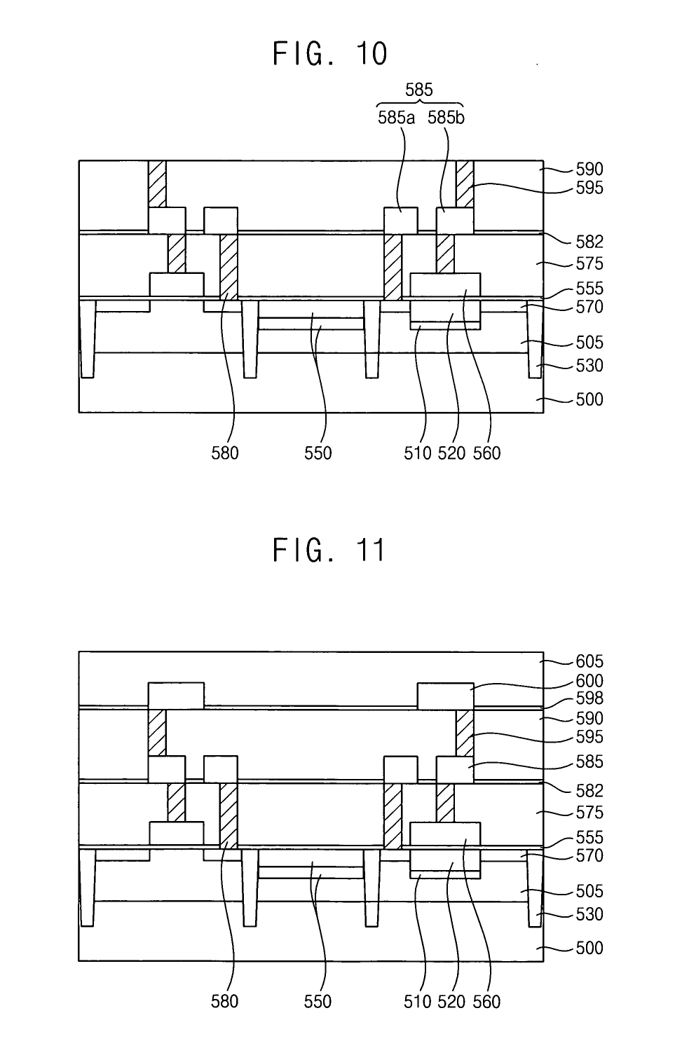

Referring to FIG. 10, an etch stop layer 582 may be formed on the first insulating interlayer 575. First via holes may be formed through the first insulating interlayer 575 to expose the gate structure 560 and the source/drain regions 570. The first via holes may be filled with first metal contacts 580. The first metal contacts 580 may electrically make contact with the gate structure 560 and the source/drain regions 570.

First metal wirings 585 may be formed on the first metal contacts 580. In example embodiments of the inventive concepts, the first metal wirings 585 may include a first left metal wiring 585a and a first right metal wiring 585b. The first left metal wiring 585a may be arranged adjacent to the photodiode 550. The first metal wiring 585 may be bent against the photodiode 550 to enlarge an area of a light-receiving region in the photodiode 550. The first metal wirings 585 may be electrically connected with a Vₒᵤₜ terminal.

A second insulating interlayer 590 may be formed on the etch stop layer 582 to cover the first metal wirings 585. In example embodiments of the inventive concepts, the second insulating interlayer 590 may be formed by a CVD process. The second insulating interlayer 590 may be planarized by a CMP process.

Via holes may be formed through the second insulating interlayer 590 to expose the first right metal wiring 585b. The via holes may be filled with the second metal contacts 595. The second metal contacts 595 may electrically make contact with the first right metal wiring 585b. In example embodiments of the inventive concepts, the second metal contacts 595 may include copper.

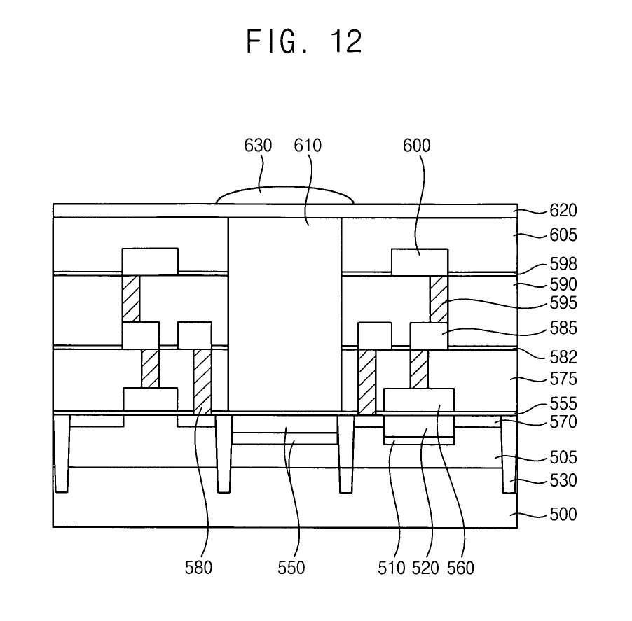

Referring to FIG. 11, an etch stop layer 598 may be formed on the second insulating interlayer 590. Second metal wirings 600 may be formed on the second metal contacts 595. The second metal wirings 600 may be bent toward the photodiode 550. In example embodiments of the inventive concepts, the second metal wirings 600 may be electrically connected with a V_{dd} terminal.

In example embodiments of the inventive concepts, the second metal wirings 600 may be located over the first metal wirings 585. A bridge may not be formed between the first metal wirings 585 and the second metal wirings 600. The photodiode 550 may have a substantially large light-receiving area so that the image sensor may have increased light receiving efficiency.

A protecting layer 605 may be formed on the etch stop layer 598 to cover the second metal wirings 600.

Referring to FIG. 12, the protecting layer 605, the second insulating interlayer 590 and the first insulating interlayer 575 may be etched to form a light-introducing hole configured to expose the photodiode 550. The light-introducing hole may be filled with an oxide layer or a transparent resin 610. The transparent resin 610 may be planarized by a CMP process.

A color filter layer 620 may be formed on the protecting layer 605 and the transparent resin 610. In other example embodiments of the inventive concepts, other portions of the color filter layer 620, except for a portion of the color filter layer 620 over the transparent resin 610 may be removed.

A micro lens 630 may be formed on the color filter layer 620. A light may pass through the micro lens 630. Colors in the light may be selectively selected by the color filter layer 620. The selected colors may accumulate in the photodiode 550 through the transparent resin 610.

According to example embodiments of the inventive concepts, the second metal wiring may be positioned over the first metal wiring. As such, a bridge may not form between the first metal wiring and the second metal wiring, so that a CFPN or an RFPN may not be generated. The multi-layered metal wiring may be formed in a small space, so that the image sensor may have a substantially high integration degree.

### System

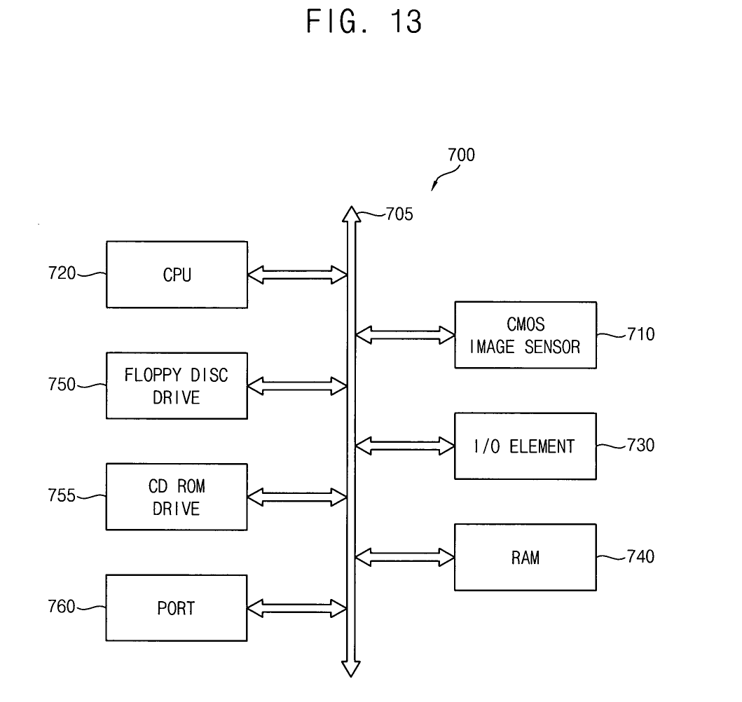

FIG. 13 is a block diagram illustrating a system in accordance with example embodiments of the inventive concepts.

Referring to FIG. 13, a system 700 may include a CMOS image sensor 710. The CMOS image sensor 710 may have elements substantially the same as those of the CMOS image sensor illustrated with reference to FIG. 1. Any further illustrations with respect to the CMOS image sensor 710 are omitted herein for brevity.

The system 700 may process images outputted from the CMOS image sensor 710. In example embodiments of the inventive concepts, the system 700 may include a computer system, a camera system, a scanner, an image stabilizing system or similar system.

If the system 700 includes the computer system, the computer system 700 may include a central processing unit (CPU) 720 (e.g., a microprocessor) communicated with input/output terminals through bus 705. The CPU 702 may be electrically coupled to a floppy disc drive 750, a CD ROM drive 755, a port 760 and an RAM 740 to receive and transmit data therebetween, thereby regenerating the images from the data of the CMOS image sensor 710.

The port 760 may be electrically coupled to other systems (e.g., a video card, a sound card, a memory card, a USB or like systems).

The CMOS image sensor 710 may be integrated with the CPU 720, a digital signal processing (DSP) unit, a microprocessor or similar device. Alternatively, the CMOS image sensor 710 may be integrated with a memory. The CMOS image sensor 710 may be integrated independently of the CPU 720.

### CMOS Image Sensing Device

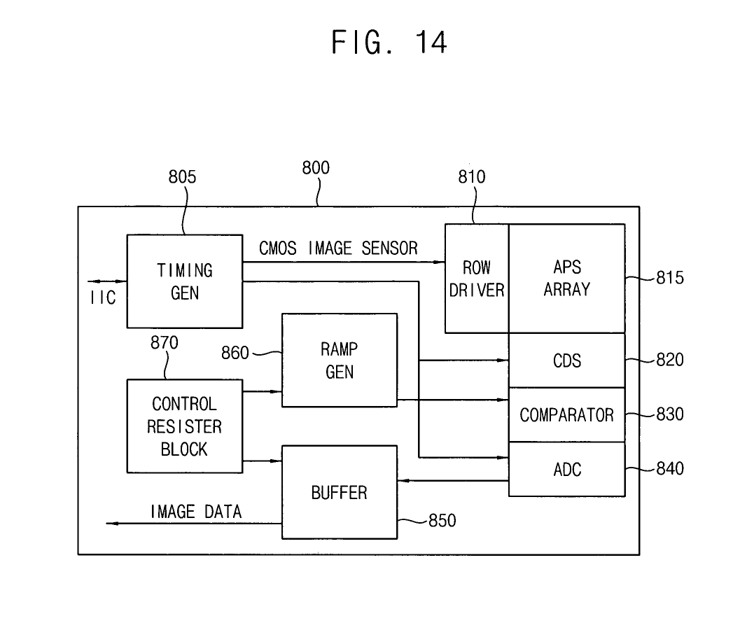

FIG. 14 is a block diagram illustrating a CMOS image sensing device in accordance with example embodiments of the inventive concepts.

Referring to FIG. 14, a CMOS image sensing device 800 may include a timing generator 805, an APS array 815, a correlated double sampler (CDS) 820, a comparator 830, an analog-to-digital convertor (ADC) 840, a buffer 850 and a control resistor block 870.

Data of a light captured in an optical lens of the APS array 815 may be converted into electrons. The electrons may be amplified by a voltage conversion. The CDS 820 may remove noises from the amplified electrons to select desired signals. The comparator 830 may compare the selected signals with each other. The ADC 840 may convert the compared signal data into digital signals. The digital signals may be transmitted through the buffer 850 and the digital signal processing (DSP) unit to regenerate the image.

### Camera Phone

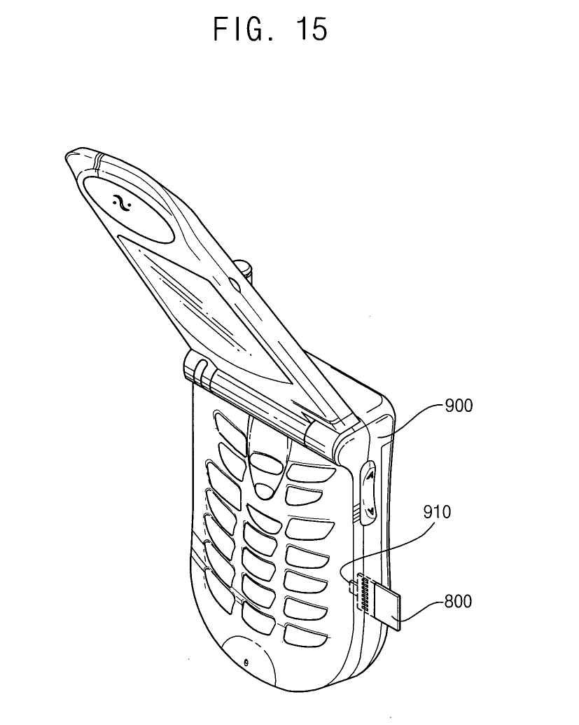

FIG. 15 is a perspective view illustrating a camera phone in accordance with example embodiments of the inventive concepts.

Referring to FIG. 15, a camera phone 900 may include a DSP 910 in which a controller (not shown) and an image signal processor (not shown) may be built. The image sensing device 800 may be electrically inserted into the DSP 910.

According to example embodiments of the inventive concepts, the CFPN and/or the RFPN may not be generated in the CMOS image sensor. As such, the CMOS image sensor may display a clear image.

The foregoing is illustrative of example embodiments of the inventive concepts and is not to be construed as limiting thereof. Although a few example embodiments of the inventive concepts have been described, those skilled in the art will readily appreciate that many modifications are possible in the example embodiments of the inventive concepts without materially departing from the novel teachings and advantages of the present invention. Accordingly, all such modifications are intended to be included within the scope of the present invention as defined in the claims. Therefore, it is to be understood that the foregoing is illustrative of various example embodiments of the inventive concepts and is not to be construed as limited to the specific example embodiments of the inventive concepts disclosed, and that modifications to the disclosed example embodiments of the inventive concepts, as well as other example embodiments of the inventive concepts, are intended to be included within the scope of the appended claims.

1. A CMOS image sensor, comprising:
an epitaxial layer on a substrate, the substrate having a photodiode region, a floating diffusion region, an active pixel sensor (APS) array circuit region and a peripheral circuit region;
a photodiode on the epitaxial layer in the photodiode region;
a transfer transistor on the epitaxial layer in the floating diffusion region;
a plurality of CMOS transistors on the epitaxial layer in the APS array circuit region and the peripheral circuit region;
a plurality of first metal wirings over the photodiode region; and
a second metal wiring on at least one of the plurality of first metal wirings, the second metal wiring being higher than the first metal wirings.

2. The CMOS image sensor of claim 1, wherein the first metal wirings are bent against a light-receiving region of the photodiode so as to enlarge an area of the light-receiving region.

3. The CMOS image sensor of claim 1, further comprising a lens over a light-receiving region of the photodiode.

4. The CMOS image sensor of claim 3, wherein the plurality of first metal wirings are bent against the light-receiving region and the second metal wiring is bent towards the light receiving-region so as to enlarge an area of the light-receiving region.

5. The CMOS image sensor of claim 3, further comprising a protecting layer covering the second metal wiring, wherein the lens is on the protecting layer.

6. The CMOS image sensor of claim 5, further comprising a color filter layer between the protecting layer and the lens.

7. The CMOS image sensor of claim 1, wherein the plurality of first metal wirings and the second metal wiring are on different insulating interlayers.

8. The CMOS image sensor of claim 1, further comprising:
a first insulating interlayer on the substrate, electrodes of the transfer transistor and electrodes of the plurality of CMOS transistors;
a plurality of first metal contacts through the first insulating interlayer and electrically connected to the photodiode, the plurality of first metal wirings being on the plurality of first metal contacts; and
a second insulating interlayer on the first insulating interlayer to cover the plurality of first metal wirings, wherein the second metal contact is formed through the second insulating interlayer.

9-18. (canceled)
